(19) United States
(12) Patent Application Publication
(10) Pub. No.: US 2006/0255333 A1
(43) Pub. Date: Nov. 16, 2006

(54) Method of forming a controlled distribution of nano-particles on a surface

(76) Inventors: Philip J. Kuekes, Menlo Park, CA (US); Zhiyong Li, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/129,602

(22) Filed: May 12, 2005

(51) Int. Cl. H01L 29/08

(52) U.S. Cl. 257/40

(57) ABSTRACT

The present invention provides a method of forming a controlled distribution of nano-particles on a surface. The method includes forming a layer of block copolymer having at least two types of blocks. Each type of block has a respective type of polymer. The block copolymer has an exposed surface and the blocks have exposed surface portions. The blocks are distributed on a substrate. The method also includes attaching nano-particles to the surface portions of at least one and less than all types of the blocks so that the attached particles form a controlled distribution on the surface of the block copolymer.

### FIELD OF THE INVENTION

The present invention relates generally to a method of forming a controlled distribution of nano-particles on a surface and to a device having a controlled distribution of nano-particles.

### BACKGROUND OF THE INVENTION

Conventional electronic devices, such as integrated electronic devices, may have structures that are as small as a micrometer. There is an interest to reduce the size of the structures further in order to improve the performance of the devices.

Nano-scale devices are now becoming of interest not only in electronics but also in biotechnology and chemistry. However, the fabrication of devices having such small structures is more challenging and typically conventional fabrication techniques, such as those involving lithography, cannot be used.

In an attempt to develop fabrication methods which are suitable for the fabrication of nano-scale devices, it may be considered to fabricate such nano-scale devices by directly assembling nano-particles. However, assembling nano-particles is very difficult and there is a need for advanced technological solutions.

### SUMMARY OF THE INVENTION

Briefly, an embodiment provides a method of forming a controlled distribution of nano-particles on a surface. The method includes forming a layer of block copolymer having at least two types of blocks. Each type of block has a respective type of polymer. The block copolymer has an exposed surface and the blocks have exposed surface portions. The blocks are distributed on a substrate. The method also includes attaching nano-particles to the surface portions of at least one and less than all types of the blocks so that the attached particles form a controlled distribution on the surface of the block copolymer.

The invention will be more fully understood from the following description of embodiments of the invention. The description is provided with reference to the accompanying drawings.

### BRIEF DESCRIPTION OF THE DRAWINGS

FIG. 1 is a flow chart illustrating a method of forming a controlled distribution of nano-particles on a surface according to an embodiment of the present invention;

FIG. 2 is a schematic side-view of a support structure for supporting molecules according to an embodiment of the present invention; and

FIG. 3 is a schematic cross-sectional representation of a sensor for sensing molecules according to an embodiment of the present invention.

### DETAILED DESCRIPTION OF EMBODIMENTS

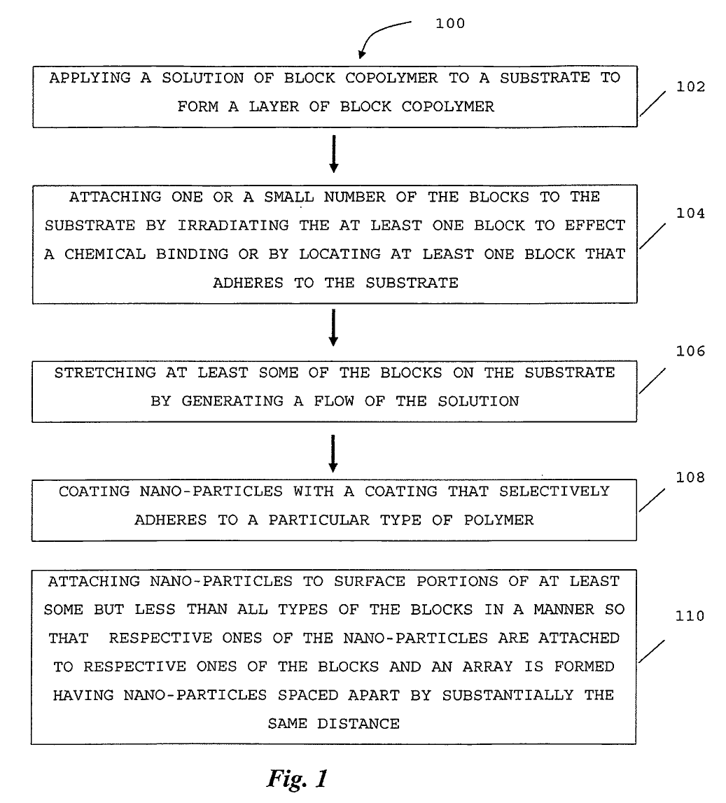

Referring initially to FIG. 1, a method of forming a controlled distribution of nano-particles on a surface is now described. FIG. 1 illustrates the method 100 which includes step 102 of applying a solution of a copolymer to a substrate. Alternatively a solution of monomers may be applied to the substrate and the polymers may be formed from the monomers on the substrate.

The types of polymer are selected so that a block copolymer is formed on the substrate. In this embodiment, a first type of polymer forms first blocks and a second type of polymer forms second blocks. The first blocks are surrounded by the second blocks. In this example the block copolymer includes two types of polymer, but in variations of this embodiment the block copolymer may also include more than two types of polymers.

In step 104 one or a small number of the blocks are then attached to the substrate. For example, this may be effected by irradiating a suitable block of the block copolymer with UV radiation to effect chemical binding between the substrate and the irradiated block. Alternatively the block copolymer may include one or more blocks which adhere or bind to the substrate when in the proximity of the substrate without UV radiation. The block at least one block that is selected for attachment typically is located in the proximity of a termination of the block co-polymer.

Step 106 generates a flow of the solution which comprises a solvent and the block co-polymer. For example, additional solvent may be moved using a pump and directed to the substrate so that the solvent together with portions of the block-copolymer flow over the substrate. Alternatively, the substrate may be tilted from a horizontal position to an angled position so that gravity effects the flow. In this case additional solvent typically is fed to an upper portion of the tilted substrate so that a continuous flow is possible. The flow is generated in a direction away from the at least one block that is attached to the substrate so that the flow causes a force on the blocks which are not attached to the substrate. This force stretches and distributes the unattached blocks in a non-reversible manner. This reduces the likelihood that monomers bind to each other to form multi-layer and as a result, an improvement in the uniformity of the block co-polymer is achieved. Further, by controlling the flow of the solution it is possible to control the stretching and therefore the extension of the blocks. Once the flow of the solution is stopped weak binding forces between the blocks of the copolymer and the substrate keep the blocks in the extended position. It is to be appreciated that steps 104 and 106 are optional and the block-co-polymer may alternatively be applied to the substrate without stretching. solute

The nano-particles may be formed from any suitable material but are typically formed from platinum, silver or gold. The polymers and the nano-particles are selected so that the nano-particles selectively bind to respective types of the polymer for example by van der Waals, hygrogen, or ionic bondings. Alternatively, this may also include step 108 of coating the nano-particles with a material, such as sulphur, that selectively bonds to a particular type of polymeric material.

In step 110 at least some but less than all nano-particles are then attached to surface portions of the block copolymer. In this example the copolymer and the nano-particles are selected so that the nano-particles selectively adhere to one type of the polymer. In this embodiment, the blocks of the copolymer form a pattern or array and as the nano-particles are selected to adhere only to one type of the polymers, a pattern or an array of the nano-particles is formed on the surface of the copolymer. Adjacent nano-particles are separated by a distance corresponding to a size of those blocks to which the nano-particles do not selectively adhere or bind. As step 106 stretches the blocks and thereby controls the extension of the blocks, step 106 also controls the distance between adjacent nano-particles.

The Method 100 has the significant advantage in that structures having controlled distributed nano-particles, such as patterns or arrays of the nano-particles, can be fabricated in a relatively simple manner by using block copolymers to form the controlled distribution. For example, each nano-particle may have a diameter of less than 50 nm, typically less than 20, 10 or 5 nm. The dimension of each block of the block copolymer may be similar and in this case only one respective nano-particle will selectively attach to one respective blocks of the block copolymer. A pattern may be formed in which adjacent nano-particles are separated by a distance that corresponds to the dimension of the nano-particles. Alternatively, the pattern may be formed so that a range of different gaps are formed between adjacent nano-particles. It is to be appreciated by the person skilled in the art that any suitable polymeric material that forms block co-polymers may be used in method 100.

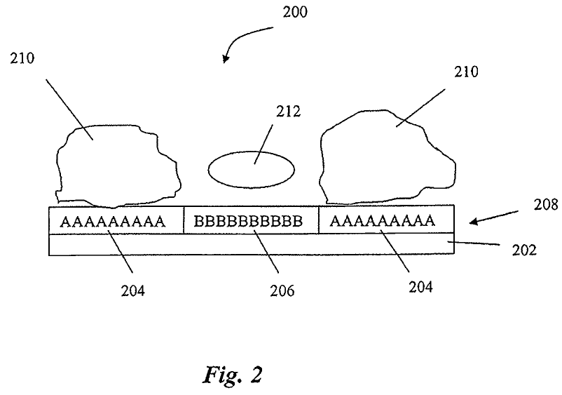

FIG. 2 shows a support structure 200 for supporting molecules according to another embodiment. The support structure 200 includes a substrate 202 on which blocks 204 and 206 of a block copolymer 208 were formed according to the above described method. Nano-particles 210 were then attached to blocks 204 of the block copolymer 208. The length of the blocks 204 and 206 and the diameters of the nano-particles 210 were chosen so that molecules 212 can be positioned in gaps formed between adjacent nano-particles 210. In this example, the gaps approximate 1-10 times a length of a molecule 212.

For example, the support structure 200 may be an array comprising a large number, such as 10³-10⁶ or more, of nano-particles 210 attached to respective blocks 204. Such a support structure 200 can be used to support a large number of molecules and may, for example, provide a support for testing the molecules. The support structure 200 may comprise gaps that equal a dimension of the non-particles. The gaps may all be substantially equal, or a range or different gaps may be formed between the nano-particles. Further, the nano-particles may all be of approximately the same size or may have a range of different sizes.

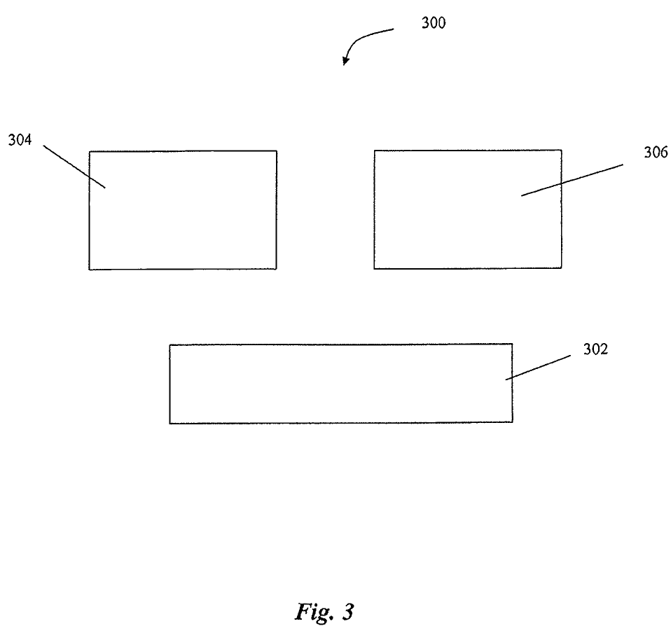

FIG. 3 shows a sensor system according to a further embodiment. In this embodiment, the system is a system for enhanced Raman scattering (SERS). The system 300 includes a support structure 302 for supporting molecules which in this embodiment is identical to the support structure 200 described above and shown in FIG. 2. The system 300 further includes a photon source, in this embodiment a laser 304, which is used to irradiate molecules supported by the support structure 302. Radiation detector 306 is used to detect a response from the absorbed molecules.

It is known that molecules show an enhanced response in Raman scattering if the molecules are positioned adjacent nano-particles having a particular size in the order of 10 to 100 nm, such as 20 nm. The enhanced Raman scattering response typically is many orders of magnitude larger than a response in conventional Raman scattering. In this embodiment, the nano-particles have dimensions and are distributed so that supported nano-particles show the enhanced Raman scattering response. For example, the gaps between adjacent nano-particles of the support structure 302 may all be substantially equal and the size of the nano-particles may also be substantially equal so that the support structure is dedicated for the detection of molecules of a particular size or type. Alternatively, different nano-particles may have different sizes and/or different gaps between them so that the support structure is suitable for detection of a range of different types of molecules which may have different dimensions.

The enhanced Raman scattering response from the molecules is detected by detector 306 and is then used to identify the supported molecules. The sensitivity of the sensor system 300 is significantly improved compared with conventional systems for sensing molecules as the Raman scattering is enhanced. The sensitivity of the sensor system 300 may be further improved if the support structure 302 supports a large number of the molecules. For example, the support structure 302 may be an array for supporting a large number of the molecules.

Although the invention has been described with reference to particular examples, it will be appreciated by those skilled in the art that the invention may be embodied in many other forms. For example, the co-polymer may include three or more types of polymer, all of which may form respective blocks which are distributed. Further, the nano-particles and the polymers may be selected so that the nano-particles selectively bind or adhere to more than one type of the polymers. Further, the support structure may by used for a range of applications. For example, the support structure may be used as a pressure sensor in which a tunnelling current between adjacent nano-particles gives a measure for a pressure applied to the support structure.

What claimed is:

1. A method of forming a controlled distribution of nano-particles on a surface, comprising:
forming a layer of block copolymer comprising at least two types of blocks, each type of block comprising a respective type of polymer, the block copolymer having an exposed surface and the blocks having exposed surface portions, the blocks being distributed on a substrate; and
attaching nano-particles to the surface portions of at least one and less than all types of the blocks so that the attached particles form a controlled distribution on the surface of the block copolymer.

2. The method of claim 1 wherein:
attaching the nano-particles comprises attaching respective ones of the nano-particles to respective ones of the blocks.

3. The method of claim 1 wherein:
the nano-particles are attached so that adjacent ones of the nano-particles are spaced apart by a distance and wherein for at least the majority of the nano-particles the distance is substantially the same.

4. The method of claim 1 wherein:
attaching the nano-particles comprises forming a pattern of the nano-particles.

5. The method of claim 1 wherein:
attaching the nano-particles comprises forming an array of the nano-particles.

6. The method of claim 1 wherein:
an extension of a respective type of block and a dimension of a respective type of nano-particle are of the same order of magnitude.

7. The method of claim 1 wherein:
an extension of each block and a dimension each nano-particle are of the same order of magnitude.

8. The method of claim 1 wherein:
an extension of each block and a dimension of each nano-particle are approximately equal.

9. The method of claim 1 comprising applying a material to the nano-particles, the material being selected to selectively bond to a particular type of the polymer.

10. The method of claim 1 wherein:
forming a layer of block copolymer comprises applying a solution of the block copolymer to the substrate.

11. The method of claim 10 wherein:
forming a layer of block copolymer comprises attaching at least one block of the block co-polymer of the solution to the substrate; and
stretching the block copolymer in a non-reversible manner so as to control the distribution of the blocks thereby the distribution of the nano-particles.

12. The method of claim 11 wherein:
stretching the block copolymer comprises applying a flow to the solution which stretches at least some of the blocks of the block copolymer.

13. The method of claim 11 wherein:
attaching at least one block of the block co-polymer comprises irradiating the at least one block to effect a chemical reaction that binds the at least one block to the substrate.

14. The method of claim 11 wherein:
the block copolymer comprises at least one block that adheres to the substrate and attaching the at least one block to the substrate comprises locating the at least one block in the proximity of the substrate.

15. A nano-structure device having a controlled distribution of nano-particles on a surface, the device comprising:
a base surface;
a layer of block copolymer on the base surface, the layer of block co-polymer comprising at least two types of blocks, each type of block comprising a respective type of polymer, the block copolymer having a surface and the blocks having surface portions, the blocks being distributed on a substrate; and
a plurality of nano-particles being attached to at least one and less than all types of the blocks so that the attached particles form a controlled distribution.

16. The device of claim 15 wherein:
at least a majority of one type of the blocks form islands surrounded by another type of the blocks.

17. The device of claim 15 wherein:
respective ones of the nano-particles are attached to respective types of the blocks.

18. The device of claim 15 wherein:
adjacent nano-particles are spaced apart by a distance and wherein for at least the majority of the nano-particles the distance is substantially the same.

19. The device of claim 15 wherein:
the nano-particles form a pattern.

20. The device of claim 15 wherein:
the nano-particles form an array.

21. The device of claim 15 wherein:
the nano-particles have a dimension that is smaller than 50 nm.

22. The device of claim 15 wherein:
the nano-particles have a dimension that is smaller than 20 nm.

23. The device of claim 15 wherein:
the nano-particles have a dimension that is smaller than 10 nm.

24. The device of claim 15 wherein:
the nano-particles are attached so that adjacent ones of the nano-particles are spaced apart by a distance and wherein for at least the majority of the nano-particles a dimension of the nano-particles and the distance are substantially equal.

25. The device of claim 15 wherein:
each block comprises less than 50 monomers.

26. The device of claim 15 wherein:
each block comprises less than 20 monomers.

27. The device of claim 15 wherein:
at least the majority of adjacent ones of the nano-particles are separated by a distance of less than 20 nm.

28. A support structure for supporting molecules, the support structure comprising:
a base surface;
a layer of block copolymer on the base surface, the layer of block co-polymer comprising at least two types of blocks, each type of block comprising a respective type of polymer, the block copolymer having a surface and the blocks having surface portions, the blocks being distributed on a substrate; and
a plurality of nano-particles being attached to the surface portions of at least one and less than all types of the blocks so that the attached particles form a controlled distribution on the surface;
wherein adjacent ones of the nano-particles are spaced apart by a distance that is selected so that an absorption position for a molecule is provided between the adjacent ones of the nano-particles.

29. The support structure of claim 28 wherein:
the distance is substantially the same for all adjacent ones of the nano-particles.

30. The support structure of claim 28 wherein:
at least some of the nano-particles are separated by a distance that differs from a distance that separates other ones of the nano-particles.

30. The support structure of claim 28 wherein:
a dimension of the nano-particles approximates a dimension of the molecule.

31. A system for enhanced Raman scattering, the system comprising:
the support structure of claim 28;
a photon source for irradiating the molecules; and a photon detector for detecting a response from the molecules.

32. A sensor for sensing molecules, the sensor comprising:
the support structure of claim 28;
a photon source for irradiating the molecules; and
a photon detector for detecting a response from the molecules and identifying the molecules.

33. The sensor of claim 32 wherein:
the distance is substantially the same for all adjacent ones of the nano-particles so that detection of one type of molecule is facilitated.

34. The support structure of claim 32 wherein:
at least some of the nano-particles are separated by a distance that differs from a distance that separates other ones of the nano-particles so that detection of different types of molecules is facilitated.
